(19) United States
(12) Patent Application Publication
(10) Pub. No.: US 2026/0190880 A1
(43) Pub. Date: Jul. 2, 2026

(54) SELECTIVE METAL PASSIVATION OF CARBON AND NITROGEN CONTAINING LAYERS

(71) Applicant: Lam Research Corporation, Fremont, CA (US)

(72) Inventors: Sriharsha JAYANTI, Fremont, CA (US); Gerardo DELGADINO, Milpitas, CA (US); Merrett WONG, Palo Alto, CA (US); Kunyi ZHANG, Shelby Twp, MI (US); Anuj BHARGAVA, Fremont, CA (US); Young Doo JEONG, Campbell, CA (US); Aniruddha JOI, Milpitas, CA (US)

(21) Appl. No.: 19/131,824

(22) PCT Filed: Dec. 8, 2023
(86) PCT No.: PCT/US2023/083147

§ 371 Date: May 21, 2025

Related U.S. Application Data
(60) Provisional application No. 63/431,460, filed on Dec. 9, 2022.

(51) Int. Cl. H10P 14/43; H10P 14/40; H10P 50/00; H10W 74/01; H10W 74/43

(52) U.S. Cl. CPC H10P 14/432; H10P 14/412; H10P 50/73; H10W 74/01; H10W 74/43

(57) ABSTRACT

A method for processing a stack comprising a silicon oxide layer and a dielectric layer comprising at least one of nitrogen and carbon is provided. A metal containing passivation layer is selectively deposited on surfaces of the dielectric layer comprising at least one of nitrogen and carbon with respect to surfaces of the silicon oxide layer, comprising flowing a metal containing passivation gas, forming the metal containing passivation gas into a plasma, and exposing the stack to the plasma, wherein the plasma selectively deposits a metal containing passivation layer on the surfaces of the dielectric layer comprising at least one of nitrogen and carbon with respect to surfaces of the silicon oxide layer.

### CROSS-REFERENCE TO RELATED APPLICATION

This application claims the benefit of priority of U.S. Application No. 63/431,460, filed Dec. 9, 2022, which is incorporated herein by reference for all purposes.

### BACKGROUND

The background description provided here is for the purpose of generally presenting the context of the disclosure. Information described in this background section, as well as aspects of the description that may not otherwise qualify as prior art at the time of filing, are neither expressly nor impliedly admitted as prior art against the present disclosure.

The disclosure relates to methods of forming semiconductor devices on a semiconductor wafer. More specifically, the disclosure relates to the passivation of sidewalls of carbon and nitrogen containing layers in the formation of semiconductor devices.

The smallest feature dimensions of semiconductor devices are constantly shrinking to follow Moore's law. In the formation of some semiconductor devices, features with small widths and high aspect ratios are etched into silicon oxide (SiO₂) layers.

### SUMMARY

To achieve the foregoing and in accordance with the purpose of the present disclosure, a method for processing a stack comprising a silicon oxide layer and a dielectric layer comprising at least one of nitrogen and carbon is provided. A metal containing passivation layer is selectively deposited on surfaces of the dielectric layer comprising at least one of nitrogen and carbon with respect to surfaces of the silicon oxide layer, comprising flowing a metal containing passivation gas, forming the metal containing passivation gas into a plasma, and exposing the stack to the plasma, wherein the plasma selectively deposits a metal containing passivation layer on the surfaces of the dielectric layer comprising at least one of nitrogen and carbon with respect to surfaces of the silicon oxide layer.

These and other features of the present disclosure will be described in more detail below in the detailed description and in conjunction with the following figures.

### BRIEF DESCRIPTION OF THE DRAWINGS

The present disclosure is illustrated by way of example, and not by way of limitation, in the figures of the accompanying drawings and in which like reference numerals refer to similar elements and in which:

FIG. 1 is a high level flow chart of an embodiment.

FIGS. 2A-I are schematic cross-sectional views of structures processed according to some embodiments.

FIGS. 3A-B are graphs of CDs from a structure processed according to some embodiments.

FIG. 4 is a schematic view of an etch chamber that may be used in some embodiments.

FIG. 5 is a schematic view of a computer system that may be used in practicing some embodiments.

In the drawings, like reference numerals are sometimes used to designate like structural elements. It should also be appreciated that the depictions in the figures are diagrammatic and not to scale.

### DETAILED DESCRIPTION OF THE EXEMPLARY EMBODIMENTS

The present disclosure will now be described in detail with reference to a few exemplary embodiments thereof as illustrated in the accompanying drawings. In the following description, numerous specific details are set forth in order to provide a thorough understanding of the present disclosure. It will be apparent, however, to one skilled in the art, that the present disclosure may be practiced without some or all of these specific details. In other instances, well-known process steps and/or structures have not been described in detail in order to not unnecessarily obscure the present disclosure.

In the formation of semiconductor devices, a stack with one or more dielectric layers may be etched. In some embodiments, the stack comprises one or more nitrogen or carbon containing layers, such as one or more layers of silicon carbide (SiC), silicon nitride (SiN), silicon oxynitride (SiON), amorphous carbon (ACL), and silicon carbonitride (SiCN). Conventional processes for etching features in dielectric layers use hydrocarbons, fluorocarbons, or hydrofluorocarbons to passivate feature sidewalls and control CDs. As the feature CDs shrink, conventional processes suffer from multiple issues, including the limited capability to control CDs, mask profile, and mask morphology. Depending on the application, such issues can sometimes be mitigated with advanced RF pulsing capabilities. However, this usually leads to tradeoffs or compromises in the etch profiles. For etching a silicon nitride layer or silicon carbide layer under a silicon mask or carbon containing mask, when hydrocarbons, fluorocarbons, or hydrofluorocarbons are used for passivation, passivation deposits near an opening of the polysilicon mask, causing necking. When too much passivation builds up near the opening of the polysilicon mask, the etch features may become tapered or the buildup may cause etch stop. The necking causes a change of etch rate and CD, making etch rate control and CD control more difficult. Various parameters, such as power, pressure, bias, flow, and gas ratios may be used to reduce taper and etch stop and control aspect ratio. However, the adjustment of such parameters can affect bowing, etch selectivity, CD, and other characteristics of the etch features.

Some embodiments provide a method for selectively forming passivation on the sidewall surfaces of nitrogen and carbon containing layers with respect to the sidewall surfaces of silicon oxide layers. In some embodiments, the silicon oxide layers may have impurities or dopants. In some embodiments, the silicon oxide layer is free of both carbon and nitrogen. The passivation may be provided after features are etched in the nitrogen and carbon containing layers and the silicon oxide layers. Subsequent etching may then be provided to further etch the silicon oxide layers.

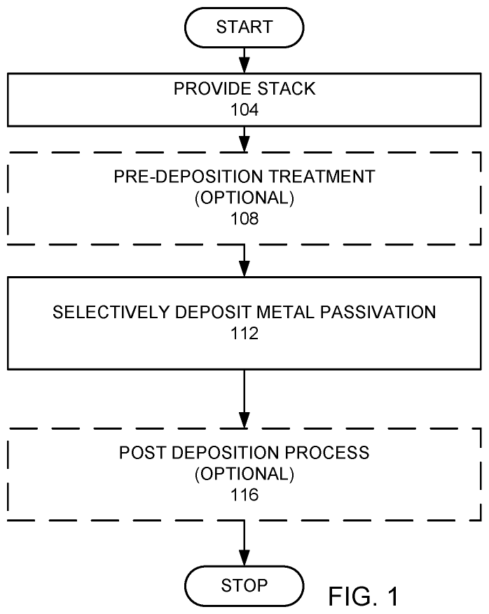

In order to facilitate understanding, FIG. 1 is a high level flow chart of a process used in some embodiments. A stack is provided (step 104) into an etch chamber. In some embodiments, the stack of one or more dielectric layers comprising at least one of nitrogen and carbon over one or more dielectric silicon oxide layers. In some embodiments, the dielectric layer comprising at least one of nitrogen and carbon may be one or more of silicon carbide, silicon nitride, silicon oxynitride, and amorphous carbon.

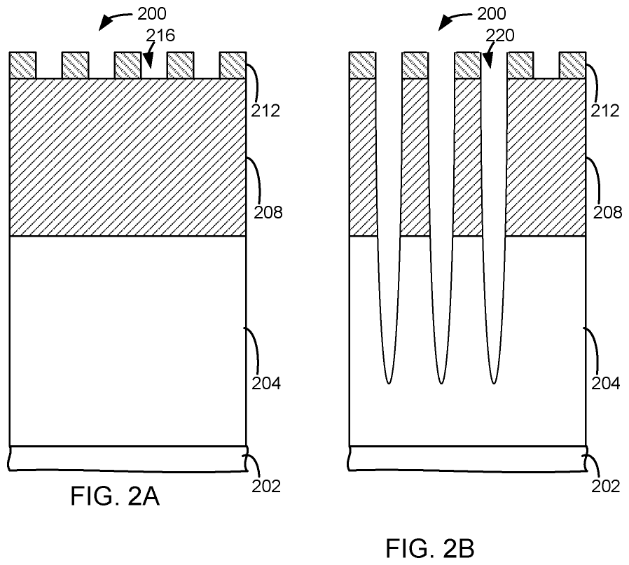

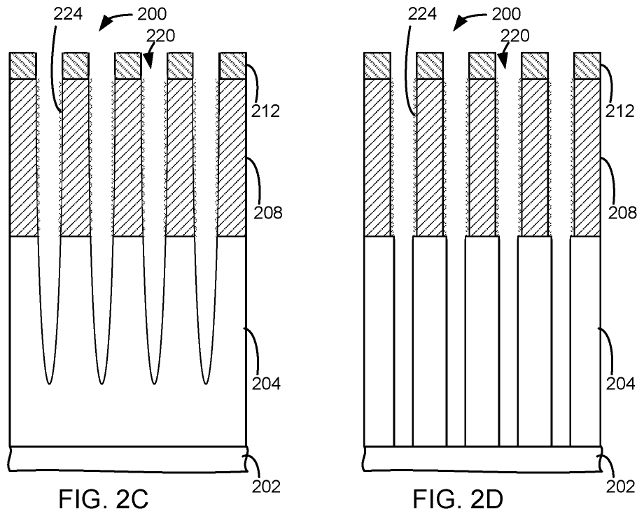

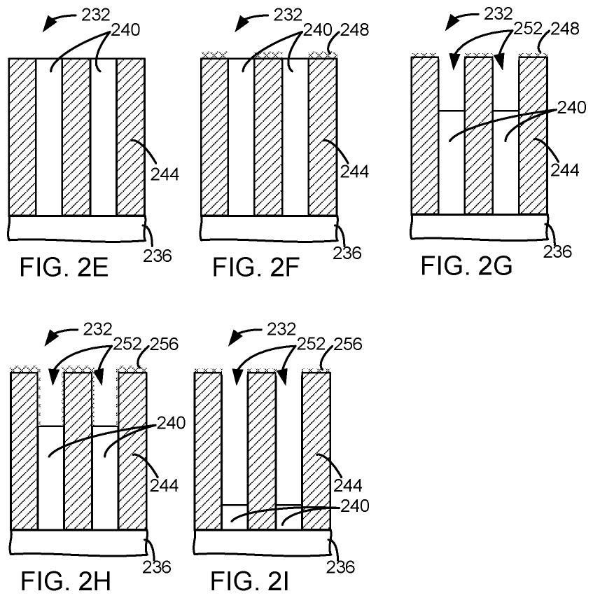

FIG. 2A is a schematic cross-sectional view of part of a stack 200 that may be used in some embodiments. A silicon oxide layer 204 is over a substrate 202, such as a wafer, and under a dielectric layer comprising at least one of nitrogen and carbon 208 under a mask 212. The mask 212 is patterned forming mask features 216. One or more layers may be between the substrate 202 and the silicon oxide layer 204. In some embodiments, the mask 212 is silicon, and the dielectric layer comprising at least one of nitrogen and carbon 208 is at least one of SiC, SiN, SiON, SiCN, and ACL.

An optional pre-deposition treatment is provided in some embodiments (step 108). In some embodiments, the pre-deposition comprises a partial etch of the dielectric layer comprising at least one of nitrogen and carbon 208 and the SiO₂ layer 204, with respect to the mask 212.

The partial etch may be a conventional etch process. In some embodiments, a conventional etch process may form carbon containing passivation on sidewalls of features etched in the dielectric layer comprising at least one of nitrogen and carbon 208. In some embodiments, the partial etch provides an etchant gas that is formed into a plasma. In some embodiments, the etchant gas comprises an oxygen containing component or a halogen containing component. In some embodiments, the oxygen containing component comprises at least one of oxygen (O₂), ozone (O₃), carbon dioxide (CO₂), carbon monoxide (CO), carbonyl sulfide (COS), nitrogen dioxide (NO₂), nitrate (NO₃), and sulfur dioxide (SO₂). In some embodiments, the halogen containing component comprises at least one of a hydrofluorocarbon (CₓH_{y}F_{z}), such as fluoromethane (CH₃F), difluoromethane (CH₂F₂), and fluoroform (CHF₃), a fluorocarbon (CₓF_{y}), such as carbon tetrafluoride (CF₄), octafluorocyclobutane (C₄F₈), and hexafluorobutadiene (C₄F₆), hydrogen bromide (HBr), hydrogen fluoride (HF), hydrogen chloride (HCl), hydrogen iodide (HI), boron trichloride (BCl₃), and chlorine (Cl₂). Generally, the etch gas has a lean chemistry to minimize the deposition of polymer in order to prevent necking.

In some embodiments, the pre-deposition treatment further comprises a cleaning process to remove carbon containing passivation. In some embodiments, the pre-deposition treatment further comprises a low energy argon (Ar) or nitrogen (N₂) cleaning.

FIG. 2B is a schematic cross-sectional view of part of the stack 200 after features 220 have been partially etched into the stack 200 through the mask 212. In some embodiments, the features 220 are etched into the dielectric layer comprising at least one of nitrogen and carbon 208 and the SiO₂ layer 204. In some embodiments, the features 220 are tapered, so that the lower parts of the features 220 have a smaller width than the upper parts of the features 220. As a result, the features 220 are wider in the dielectric layer comprising at least one of nitrogen and carbon 208 and narrower in the SiO₂ layer 204.

Next, a metal containing passivation layer is selectively deposited on sidewall surfaces of the features in the dielectric layer comprising at least one of nitrogen and carbon 208 (step 112). In some embodiments, a metal containing passivation gas is provided. In some embodiments, the metal containing passivation gas contains a component containing at least one of molybdenum (Mo), rhenium (Re), tantalum (Ta), tungsten (W), or vanadium (V). For example, the metal containing passivation gas comprises at least one of rhenium hexafluoride (ReF₆), molybdenum hexafluoride (MoF₆), tantalum pentafluoride (TaF₅), tungsten hexafluoride (WF₆), and vanadium fluoride (VF₅).

In some embodiments, the metal containing passivation gas is formed into a plasma. In some embodiments, RF excitation power is provided to transform the etch gas into a plasma. The RF power may be provided at various frequencies. In various embodiments, the RF power is provided at frequencies of at least one of 13.56 megahertz (MHz), 60 MHz, 27 MHz, 2 MHz, 1 MHz, and 400 kilohertz (kHz).

The metal containing passivation gas or plasma are used to selectively passivate the dielectric layer comprising at least one of nitrogen and carbon 208 with respect to the SiO₂ layer 204. FIG. 2C is a schematic cross-sectional view of part of the stack 200 after the metal containing passivation 224 is provided. Some metal containing passivation may be deposited on the SiO₂ layer 204 and the mask 212. The metal containing passivation 224 is schematically illustrated to show that the metal containing passivation 224 is selectively deposited on the dielectric layer comprising at least one of nitrogen and carbon 208 with respect to the SiO₂ layer 204.

An optional post-deposition treatment is provided in some embodiments (step 116). In some embodiments, the post-deposition comprises densifying or hardening the metal containing passivation 224. An argon or nitrogen gas may be used to bombard the metal containing passivation 224 to densify or harden the metal containing passivation 224 in order to make the metal containing passivation 224 more robust.

In some embodiments, the post-deposition treatment may comprise a further etch of the SiO₂ layer 204. The further etch may be a conventional etch process. In some embodiments, a conventional etch process may form carbon containing passivation on sidewall surfaces of features etched in the dielectric layer comprising at least one of nitrogen and carbon 208. In some embodiments, the further etch provides an etchant gas that is formed into a plasma. In some embodiments, the etchant gas comprises an oxygen containing component or a halogen containing component. In some embodiments, the oxygen containing component comprises at least one of oxygen (O₂), ozone (O₃), carbon dioxide (CO₂), carbon monoxide (CO), carbonyl sulfide (COS), nitrogen dioxide (NO₂), nitrate (NO₃), and sulfur dioxide (SO₂). In some embodiments, the halogen containing component comprises at least one of a hydrofluorocarbon (CₓH_{y}F_{z}), such as fluoromethane (CH₃F), difluoromethane (CH₂F₂), and fluoroform (CHF₃), a fluorocarbon (CₓF_{y}), such as carbon tetrafluoride (CF₄), octafluorocyclobutane (C₄F₈), and hexafluorobutadiene (C₄F₆), hydrogen bromide (HBr), hydrogen fluoride (HF), hydrogen chloride (HCl), hydrogen iodide (HI), boron trichloride (BCl₃), and chlorine (Cl₂). Generally, the etch gas has a lean chemistry to minimize the deposition of polymer in order to prevent necking.

In some embodiments, post-deposition treatment may comprise densifying the metal containing passivation 224 followed by an etch of the SiO₂ layer 204. In some embodiments, all of the pre-deposition treatment (step 108) steps, the selective deposition of the metal passivation (step 112), and the post-deposition treatment (step 116) steps are done in-situ in the same process chamber with the stack mounted on the same chuck. In some embodiments, some of the steps may be performed in different chambers.

FIG. 2D is a schematic cross-sectional view of part of the stack 200 after a post-deposition treatment process is provided in some embodiments. A subsequent etch of the SiO₂ layer 204 further etches the features 220. The metal containing passivation 224 decreases the width of the features 220 in the dielectric layer comprising at least one of nitrogen and carbon 208 so that the features 220 in the SiO₂ layer 204 have a reduced width.

It has been found that the metal passivation layer is more etch resistant than polymer passivation. Therefore, some embodiments provide more etch resistant passivation than processes that use a polymer passivation. In addition, it has been found that the metal passivation layer is more resistant to ion bombardment than polymer passivation. Therefore, etch features with metal passivation layers are less subject to bowing.

In some embodiments, the features 220 have a width CD in the range of 15 nm to 30 nm. In some embodiments, the features 220 have a width CD in the range of 5 nm to 15 nm. In some embodiments, the mask 212 has a thickness of at least 500 nm. In some embodiments, the dielectric layer comprising at least one of nitrogen and carbon 208 has a thickness of at least 300 nm. In some embodiments, the SiO₂ layer 204 has a thickness in the range of 300 nm. In some embodiments, the metal passivation results in shrinking the features 220 in the SiO₂ layer 204 by at least 2 nm.

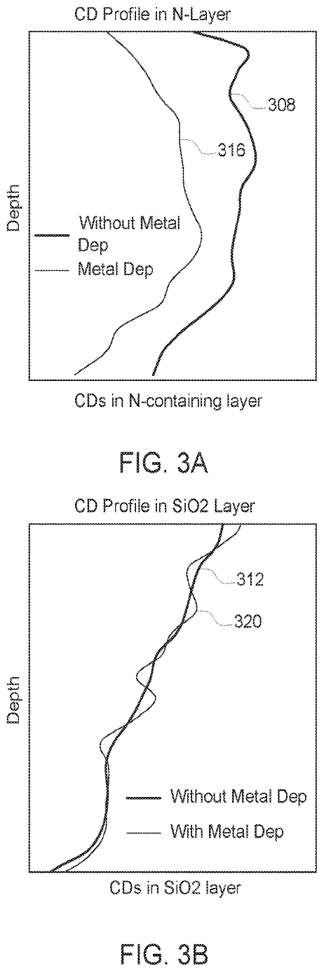

FIG. 3A is a graph that measures the CD for features in a dielectric layer comprising at least one of nitrogen and carbon 208. FIG. 3B is a graph that measures the CD for features in a SiO₂ layer 204. Baseline curves 308, 312 show CDs of a feature etched using a baseline etch process without providing metal passivation. Passivation curves 316, 320 show CDs of a feature etched using a metal passivation. Curves 308 and 316 show that providing metal passivation results in features 220 in the dielectric layer comprising at least one of nitrogen and carbon 208 that have a lower CD than a baseline process without metal passivation. Curves 312 and 320 show that the CD of features 220 in the SiO₂ layer 204 is about the same for the base line process without metal passivation and the process providing metal passivation. As a result, in some embodiments, providing a metal passivation results in a reduction of CD in the dielectric layer comprising at least one of nitrogen and carbon 208 without changing CD in the SiO₂ layer 204. In some embodiments, the metal passivation is also used to reduce tapering without increasing CD. In the example shown in FIG. 3A and FIG. 3B, the CD in the dielectric layer comprising at least one of nitrogen and carbon 208 is shrunk by 5%. In some embodiments, the CD in the dielectric layer comprising at least one of nitrogen and carbon 208 is shrunk by 15%.

In some embodiments, providing metal passivation allows for the reduction or removal of fluorocarbons from the passivation and/or etch process, so that there is minimal or no carbon passivation. In some embodiments, the etch chemistry has a high concentration of a halogen, such as fluorine, and a high bias.

In some embodiments, an additional dielectric layer comprising at least one of nitrogen and carbon may be below the SiO₂ layer 204 and an additional SiO₂ layer is below the additional dielectric layer comprising at least one of nitrogen and carbon. In some embodiments, the post-deposition treatment further etches the additional dielectric layer comprising at least one of nitrogen and carbon and the additional SiO₂ layer. In some embodiments, one or more additional cycles of providing a step selectively depositing metal passivation and providing a post-deposition process are provided to further etch the stack.

In some embodiments, the selective deposition of the metal passivation (step 112), and the post-deposition treatment (step 116) are provided simultaneously, where an etch gas and a metal containing passivation gas are provided simultaneously. Therefore, tuning may be optimized for etch selectivity and CD, without an optimization for a reduction in bowing. In some embodiments, providing both an etchant and the metal containing passivant simultaneously may provide a more robust process that allows for an optimization that helps eliminate etch stop. In some embodiments, some of the metal passivation layer may be deposited on the etch front. To prevent etch stop, sufficient bias power is provided to remove any metal passivation layer on the etch front.

### Various Embodiments

In some embodiments, the metal passivation layer comprises a metal carbide or metal nitride, where the nitrogen or carbon is provided by the dielectric layer comprising at least one of nitrogen and carbon. In some embodiments, the metal containing passivant comprises tungsten. In such embodiments, the passivation layer comprises tungsten carbide or tungsten nitride, where the nitrogen or carbon is provided by the dielectric layer comprising at least one of nitrogen and carbon. In some embodiments, the dielectric layer comprising at least one of nitrogen and carbon further comprises silicon. In some embodiments, the carbon containing layer is a carbon based etch layer, such as amorphous carbon and photoresist.

In some embodiments, the etch process may be used to provide a capacitor etch. In some embodiments, the etch process may be used in forming dynamic random access memory. In some embodiments, if the etch layer is a polysilicon layer, if the passivant is tungsten hexafluoride, elemental tungsten is deposited on sidewall surfaces of the polysilicon layer as a passivation layer instead of tungsten carbide or tungsten nitride, if nitrogen and carbon are not present during the etch process. In some embodiments, flow ratios of the different components of the etch gas may be varied during a process.

In some embodiments, the etch and passivation process may be used in the formation of logic devices. In some embodiments, a dielectric layer comprising at least one of nitrogen and carbon may be below a silicon oxide layer. The metal containing passivation gas is used to reduce vertical or lateral etching of the dielectric layer comprising at least one of nitrogen and carbon while increasing the CD of features in the silicon oxide layer above the dielectric layer comprising at least one of nitrogen and carbon.

In some embodiments, a halogen containing gas or oxygen containing gas is provided with the metal containing passivation gas. In some embodiments, the halogen containing gas or oxygen containing gas may be used to selectively remove depositions on surfaces, such as carbon containing sidewall passivation. In some embodiments, the deposition may cause necking resulting in pinch off and/or tapering. In some embodiments, the removal of deposition by halogen containing gas or oxygen containing gas reduces or eliminates necking. In some embodiments, the halogen containing gas or oxygen containing gas may further etch features in the dielectric layer comprising at least one of nitrogen and carbon or silicon oxide layers. In some embodiments, the halogen containing gas is a fluorine containing gas. In some embodiments, the oxygen containing component comprises at least one of oxygen (O₂), ozone (O₃), carbon dioxide (CO₂), carbon monoxide (CO), carbonyl sulfide (COS), nitrogen dioxide (NO₂), nitrate (NO₃), and sulfur dioxide (SO₂). In some embodiments, the halogen containing component comprises at least one of a hydrofluorocarbon (CₓH_{y}F_{z}), such as fluoromethane (CH₃F), difluoromethane (CH₂F₂), and fluoroform (CHF₃), a fluorocarbon (CₓF_{y}), such as carbon tetrafluoride (CF₄), octafluorocyclobutane (C₄F₈), and hexafluorobutadiene (C₄F₆), hydrogen bromide (HBr), hydrogen fluoride (HF), hydrogen chloride (HCl), hydrogen iodide (HI), boron trichloride (BCl₃), and chlorine (Cl₂).

In some embodiments, the metal containing passivation gas deposits on surfaces that may be sidewall surfaces of features. In some embodiments, the metal containing passivation gas deposits on surfaces that may be on top surfaces of the stack. FIG. 2E is a schematic cross-sectional view of part of a stack 232 over a substrate 236 that may be used in some embodiments where silicon oxide 240 fills gaps between silicon nitride structures 244. In the specification and claims the silicon nitride structures 244 may be called silicon nitride layers and the silicon oxide 240 filling the gaps may be called silicon oxide layers.

In order to selectively etch the silicon oxide 240, a selective metal passivation is deposited on the silicon nitride structures 244 with respect to the silicon oxide 240 (step 112). A metal containing passivation gas is provided. The metal containing passivation gas is formed into a plasma. The stack 232 is exposed to the plasma, wherein the plasma selectively deposits a metal containing passivation layer on the surfaces of the silicon nitride 244 with respect to the surfaces of the silicon oxide 240. FIG. 2F is a schematic cross-sectional view of part of a stack 232 after a metal containing passivation layer 248 has been selectively deposited on the silicon nitride structures 244 with respect to the silicon oxide 240.

A post deposition process is provided (step 116) by etching the stack 232. FIG. 2G is a schematic cross-sectional view of part of a stack 232 after the stack 232 has been etched. Features 252 have been selectively etched into the silicon oxide 240. The metal containing passivation layer 248 prevented or reduced the etching of the silicon nitride structures 244.

In some embodiments, another selective metal passivation is deposited on the silicon structures 244 with respect to silicon oxide 240. FIG. 2H is a schematic cross-sectional view of part of a stack 232 after another metal containing passivation layer 256 has been selectively deposited on the silicon nitride structures 244 with respect to the silicon oxide 240. The metal containing passivation layer 256 is deposited both on top and sidewalls of the silicon nitride structures 244.

The silicon oxide 240 is further etched. FIG. 2I is a schematic cross-sectional view of part of a stack 232 after the silicon oxide 240 is further etched. In some embodiments, the silicon oxide 240 is completely etched away. Additional subsequent processes may also be performed such as removing any remaining metal containing passivation layer 256.

### Apparatus

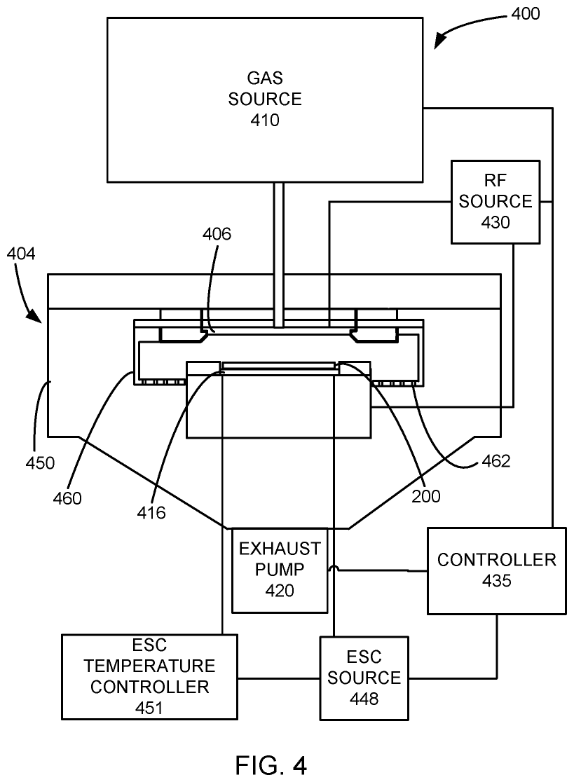

To facilitate understanding, FIG. 4 is a schematic view of a plasma processing chamber 400 for plasma processing substrates, in an embodiment. In one or more embodiments, the plasma processing chamber 400 comprises a gas distribution plate 406 providing a gas inlet and an electrostatic chuck (ESC) 416, within a plasma processing chamber 404, enclosed by a chamber wall 450. Within the plasma processing chamber 404, the stack 200 is positioned over the ESC 416 that acts as a substrate support. The ESC 416 may provide a bias from an ESC power source 448. A gas source 410 is connected to the plasma processing chamber 404 through the gas distribution plate 406. An ESC temperature controller 451 is connected to the ESC 416 and provides temperature control of the ESC 416. A radio frequency (RF) power source 430 provides RF power to the ESC 416 and an upper electrode. In this embodiment, the upper electrode is the gas distribution plate 406. In a preferred embodiment, 400 kilohertz (kHz), 13.56 megahertz (MHz), 1 MHz, 2 MHz, 60 MHz, and/or optionally, 27 MHz power sources make up the RF power source 430 and the ESC power source 448. A controller 435 is controllably connected to the RF power source 430, the ESC power source 448, an exhaust pump 420, and the gas source 410. A high flow liner 460 is a liner within the plasma processing chamber 404, which confines gas from the gas source and has slots 462. The slots 462 maintain a controlled flow of gas to pass from the gas source 410 to the exhaust pump 420. An example of such a plasma processing chamber is the Flex® etch system manufactured by Lam Research Corporation of Fremont, CA. The process chamber can be a CCP (capacitively coupled plasma) reactor or an ICP (inductively coupled plasma) reactor.

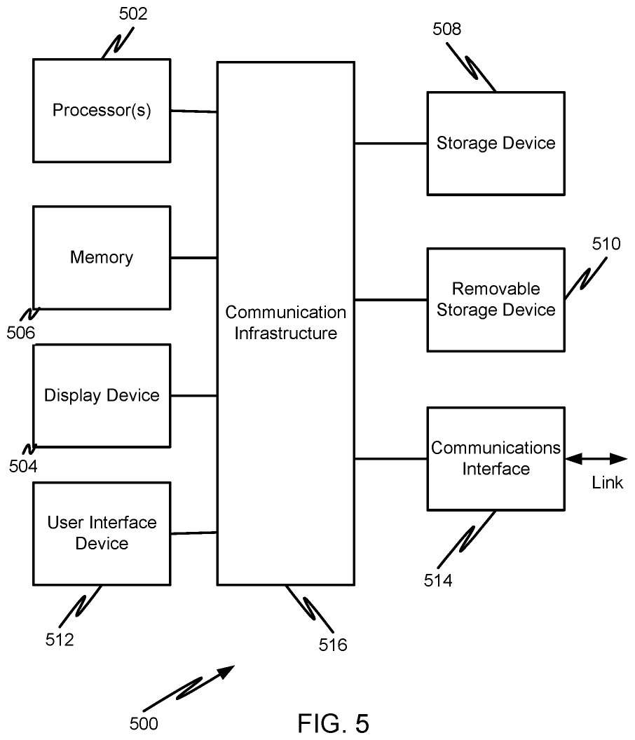

FIG. 5 is a high level block diagram illustrating a computer system 500 for implementing the controller 435 used in embodiments of the present inventions. The computer system may have many physical forms ranging from an integrated circuit, a printed circuit board, and a small handheld device up to a huge supercomputer. The computer system 500 may include one or more processors 502, and further can include an electronic display device 504 (for displaying graphics, text, and other data), a main memory 506 (e.g., random access memory (RAM)), storage device 508 (e.g., hard disk drive), removable storage device 510 (e.g., optical disk drive), user interface devices 512 (e.g., keyboards, touch screens, keypads, mice or other pointing devices, etc.), and/or a communication interface 514 (e.g., wireless network interface). The communication interface 514 may allow software and/or data to be transferred between the computer system 500 and external devices via a link. The system may also include a communications infrastructure 516 (e.g., a communications bus, cross-over bar, or network) to which the aforementioned devices/modules may be connected.

Information transferred via communications interface 514 may be in the form of signals such as electronic, electromagnetic, optical, or other signals capable of being received by communications interface 514, via a communication link that carries signals and may be implemented using wire or cable, fiber optics, a phone line, a cellular phone link, a radio frequency link, and/or other communication channels. With such a communications interface, it is contemplated that the one or more processors 502 might receive information from a network or might output information to the network in the course of performing the above-described method steps. Furthermore, method embodiments may execute solely upon the processors or may execute over a network such as the Internet in conjunction with remote processors that share a portion of the processing.

The term “non-transient computer readable medium” is used generally to refer to media such as main memory, secondary memory, removable storage, and storage devices, such as hard disks, flash memory, disk drive memory, CD-ROM, and other forms of persistent memory and shall not be construed to cover transitory subject matter, such as carrier waves or signals. Examples of computer code include machine code, such as that produced by a compiler, and files containing higher level code that are executed by a computer using an interpreter. Computer readable media may also be computer code transmitted by a computer data signal embodied in a carrier wave and representing a sequence of instructions that are executable by a processor.

While this disclosure has been described in terms of several exemplary embodiments, there are alterations, modifications, permutations, and various substitute equivalents, which fall within the scope of this disclosure. It should also be noted that there are many alternative ways of implementing the methods and apparatuses of the present disclosure. It is therefore intended that the following appended claims be interpreted as including all such alterations, modifications, permutations, and various substitute equivalents as fall within the true spirit and scope of the present disclosure. As used herein, the phrase “A, B, or C” should be construed to mean a logical (“A OR B OR C”), using a non-exclusive logical “OR,” and should not be construed to mean ‘only one of A or B or C. Each step within a process may be an optional step and is not required. Different embodiments may have one or more steps removed or may provide steps in a different order. In addition, various embodiments may provide different steps simultaneously instead of sequentially.

What is claimed is:

1. A method for processing a stack comprising a silicon oxide layer and a dielectric layer comprising at least one of nitrogen and carbon, the method comprising:
selectively depositing a metal containing passivation layer on surfaces of the dielectric layer comprising at least one of nitrogen and carbon with respect to surfaces of the silicon oxide layer, comprising:
flowing a metal containing passivation gas;
forming the metal containing passivation gas into a plasma; and
exposing the stack to the plasma, wherein the plasma selectively deposits a metal containing passivation layer on the surfaces of the dielectric layer comprising at least one of nitrogen and carbon with respect to surfaces of the silicon oxide layer.

2. The method, as recited in claim 1, wherein the metal containing passivation gas comprises at least one of molybdenum, rhenium, tantalum, tungsten, and vanadium.

3. The method, as recited in claim 1, further comprising etching features in the dielectric layer comprising at least one of nitrogen and carbon and in the silicon oxide layer before selectively depositing the metal containing passivation layer.

4. The method, as recited in claim 3, wherein the etching features in the dielectric layer comprising at least one of nitrogen and carbon and in the silicon oxide layer is provided through a mask.

5. The method, as recited in claim 4, wherein the mask is a silicon mask.

6. The method, as recited in claim 3, wherein the features in the dielectric layer comprising at least one of nitrogen and carbon have a width in a range of 15 nm to 30 nm.

7. The method, as recited in claim 1, further comprising pretreating the surfaces of the dielectric layer comprising at least one of nitrogen and carbon before selectively depositing the metal containing passivation layer.

8. The method, as recited in claim 1, further comprising densifying the metal containing passivation layer.

9. The method, as recited in claim 1, further comprising, etching the silicon oxide layer.

10. The method, as recited in claim 9, wherein the etching of the silicon oxide layer is simultaneous with the selectively depositing a metal containing passivation layer.

11. The method, as recited in claim 9, wherein the etching of the silicon oxide layer and the selectively depositing a metal containing passivation layer are provided cyclically for a plurality of cycles.

12. The method, as recited in claim 9, wherein the etching the silicon oxide layer is after selectively depositing the metal containing passivation layer.

13. The method, as recited in claim 1, wherein the dielectric layer comprising at least one of nitrogen and carbon is at least one of silicon nitride, silicon carbonitride, silicon oxynitride, silicon carbide, and amorphous carbon.

14. The method, as recited in claim 1, wherein the metal containing passivation comprises a metal carbide or metal nitride, wherein carbon for the metal carbide or nitrogen for the metal nitride is provided by the dielectric layer comprising at least one of nitrogen and carbon.

15. The method, as recited in claim 1, wherein the flowing the metal containing passivation gas, further comprises flowing a halogen containing or oxygen containing gas.

16. The method, as recited in claim 15, wherein the halogen containing or oxygen containing gas, comprises at least one of oxygen (O₂), ozone (O₃), carbon dioxide (CO₂), carbon monoxide (CO), carbonyl sulfide (COS), nitrogen dioxide (NO₂), nitrate (NO₃), sulfur dioxide (SO₂), a hydrofluorocarbon (CₓH_{y}F_{z}), such as fluoromethane (CH₃F), difluoromethane (CH₂F₂), and fluoroform (CHF₃), a fluorocarbon (CₓF_{y}), such as carbon tetrafluoride (CF₄), octafluorocyclobutane (C₄F₈), and hexafluorobutadiene (C₄F₆), hydrogen bromide (HBr), hydrogen fluoride (HF), hydrogen chloride (HCl), hydrogen iodide (HI), boron trichloride (BCl₃), and chlorine (Cl₂).

17. The method, as recited in claim 1, wherein the surfaces of the dielectric layer comprising at least one of nitrogen and carbon and surfaces of the silicon oxide layer are sidewall surfaces of features in the dielectric layer comprising at least one of nitrogen and carbon and the silicon oxide layer.
